(19) United States
(12) Patent Application Publication
(10) Pub. No.: US 2015/0173174 A1
(43) Pub. Date: Jun. 18, 2015

(54) MULTI-LAYER PRINTED CIRCUIT BOARD

(71) Applicants: SHENZHEN FUTAIHONG PRECISION INDUSTRY CO., LTD., Shenzhen (CN); Chiun Mai Communication Systems, Inc., New Taipei (TW)

(72) Inventor: SU WEI, Shenzhen (CN)

(21) Appl. No.: 14/569,986

(22) Filed: Dec. 15, 2014

(30) Foreign Application Priority Data
Dec. 18, 2013 (CN) 201310694061.8

(51) Int. Cl. H05K 1/02; H05K 1/11

(52) U.S. Cl. CPC H05K 1/0216; H05K 1/112; H05K 2201/0792; H05K 2201/09545

(57) ABSTRACT

A multi-layer printed circuit board includes a first layer, a second layer, at least one third layer, a conductive via hole, and a capacitor electronically coupled to the conductive via hole. The at least one third layer is sandwiched between the first and second layers. The conductive via hole is defined through the first, second and third layers, and having a parasitic inductance. The capacitor and the parasitic inductance of the conductive via hole cooperatively form a low-pass filter that is configured to filter noise signal induced by conductive via hole due to the parasitic inductance.

### FIELD

The subject matter herein generally relates to printed circuit boards, and particularly to a multi-layer printed circuit board.

### BACKGROUND

A typical printed circuit board (PCB) includes one or more layers of insulating material, upon which patterns of electrical conductors are formed. In addition, via holes may be formed to allow for layer-to-layer interconnections between various conductive features. However, the via holes may induce interference to the electrical conductors.

### BRIEF DESCRIPTION OF THE DRAWINGS

Implementations of the present technology will now be described, by way of example only, with reference to the attached figures.

FIG. 1 is a cross sectional view of one embodiment of a multi-layer printed circuit board.

FIG. 2 is a diagrammatic view of the multi-layer printed circuit board as shown in FIG. 1.

FIG. 3 is a circuit diagram of the printed circuit board as shown in FIGS. 1-2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

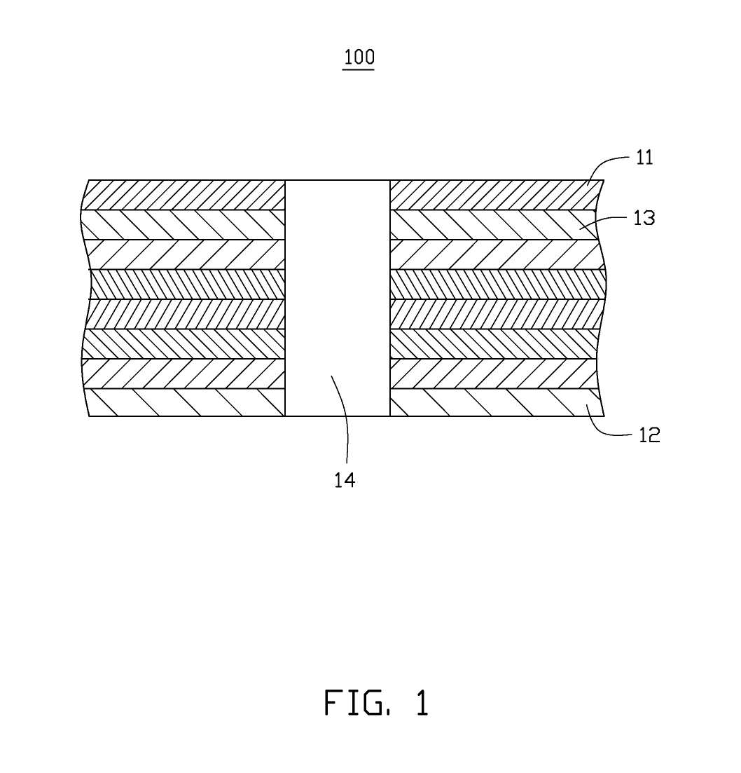

FIG. 1 illustrates a cross sectional view of one embodiment of a multi-layer printed circuit board 100 that includes a first layer 11, a second layer 12 and at least one second layer 13 sandwiched between the first and second layers 11 and 12. A conductive via hole 14 is defined through the first, second and third layers 11, 12 and 13, and is made conductive by electroplating, or is lined with a tube or a rivet. In at least one embodiment as shown in FIG. 1, six third layers 13 are sandwiched between the first and second layers 12 and 13.

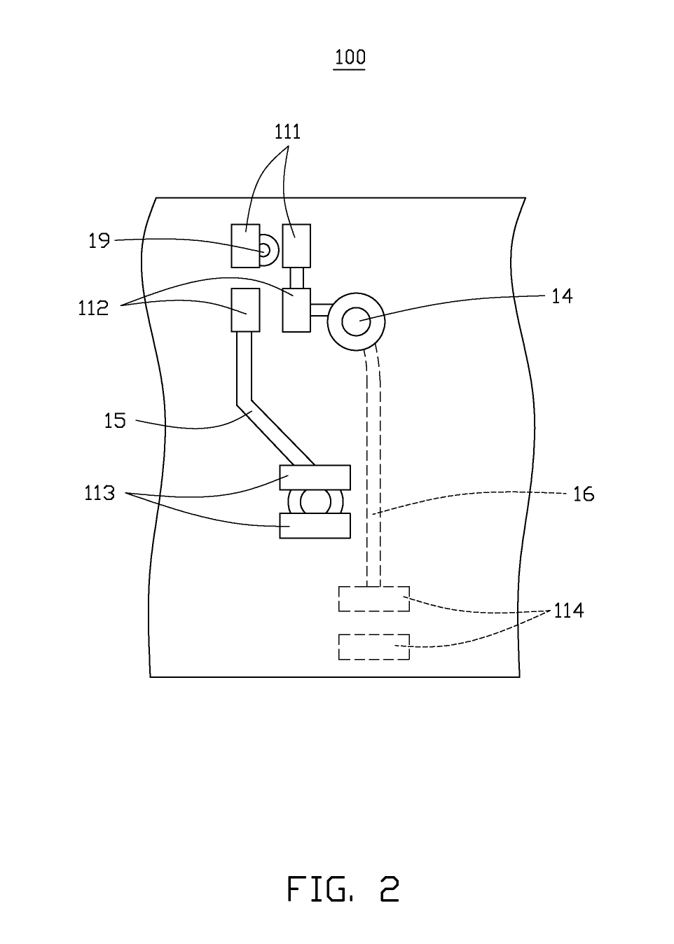

FIG. 2 illustrates a diagrammatic view of the printed circuit board 100 as shown in FIG. 1. The printed circuit board 100 further includes four pairs of pads 111, 112, 113 and 114, a first transmission line 15 and a second transmission line 16. In one embodiment, the first transmission line 15 and the three pair of pads 111, 112 and 113 are printed on the first layer 11; the second transmission line 16 and the pair of pads 114 are printed on the second layer 12 (see FIG. 1). The two pairs of pads 111 and 112 are located adjacent to and electronically coupled to the conductive via hole 14. The first transmission line 15 is electronically coupled between the pairs of pads 112 and 113. The second transmission line 16 is electronically coupled between the conductive via hole 14 and the pair of pads 114. A characteristic impedance of the first transmission line 15 is 50 ohms; a characteristic impedance of the second transmission line 16 is also 50 ohms

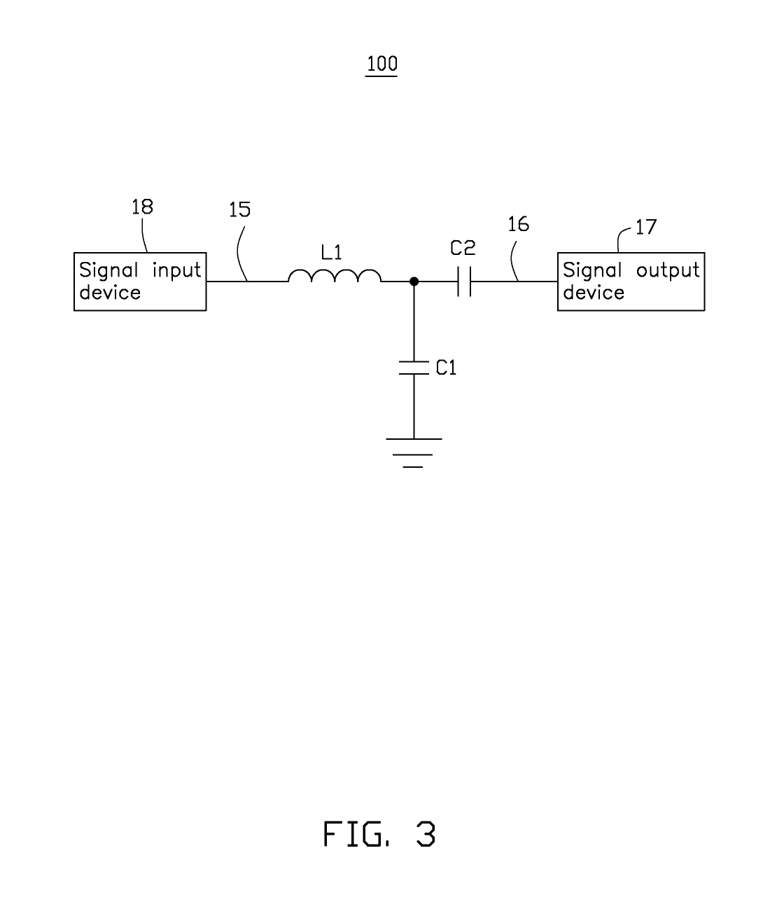

FIG. 3 illustrates a circuit diagram of the printed circuit board 100 as shown in FIGS. 1-2. The printed circuit board 100 is further provided with a signal output device 17, a signal input device 18, a filtering capacitor C1 and a transmission capacitor C2. The filtering capacitor C1, the transmission capacitor C2, the signal output device 17, and the signal input device 18 are electronically soldered to the four pairs of pads 111, 112,113, and 114 as shown in FIG. 2, respectively. The signal output device 17 is configured to output signals, such as WiFi signals, to the signal input device 18 through the conductive via hole 14 (see FIGS. 1-2). The conductive via hole 14 has a characteristic parasitic inductance L1, thus, in the equivalent circuit diagram as shown in FIG. 3, the signal output device 17 is electronically coupled to the signal input device 18 through the transmission capacitor C2 and the inductor L1. The transmission capacitor C2 is configured to facilitate transmitting signals from the signal output device 17 to the signal input device 18. The filtering capacitor C1 is electronically coupled to a node between the inductor L1 and the transmission capacitor C2, and is grounded. In at least one embodiment, the capacitor C1 is grounded through a via hole 19 (as shown in FIG. 2) that is electronically coupled to a ground layer (now shown) of the printed circuit board 100.

In use, the parasitic inductance L1 of the conductive via hole 14 may induce harmonic waves (that is noise signals) of the signal output from the signal output device 17. The filtering capacitor C2 and the inductor L1 cooperatively form a low-pass filter that is configured to eliminate the noise signal generated due to the parasitic inductance L1.

In at least one embodiment, the a length of the conductive via hole 14 is about 50 mil; a diameter of the conductive via hole 14 is about 12 mil; an inductance value of the parasitic inductance L1 is about 1 nH; a capacitance value of the filtering capacitor C1 is about 1.8 pF; and a capacitance value of the transmission capacitor C2 is about 33 pF.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A multi-layer printed circuit board comprising:
a first layer;
a second layer;
at least one third layer between the first and second layers;
a conductive via hole defined through the first, second and third layers, and having a parasitic inductance;
a filtering capacitor electronically coupled between the conductive via hole and ground, the filtering capacitor and the parasitic inductance of the conductive via hole cooperatively forming a low-pass filter that is configured to filter noise signal induced by the conductive via hole due to the parasitic inductance.

2. The multi-layer printed circuit board of claim 1, further comprising a signal output device, a signal input device, a first transmission line and a second transmission line, wherein the signal output device and signal input device are positioned on the first and second layers respectively; the signal output device is electronically coupled to an end of the conductive via hole through the first transmission line, the signal input device is electronically coupled to another end of the conductive via hole through the second transmission line.

3. The multi-layer printed circuit board of claim 2, wherein the capacitor is located on the first layer, and adjacent to the conductive via hole, and further electronically coupled between the conductive via hole and the signal output device.

4. The multi-layer printed circuit board of claim 2, wherein a characteristic impedance of the first transmission line is 50 ohms; a characteristic impedance of the second transmission line is 50 ohms

5. The multi-layer printed circuit board of claim 2, further comprising a transmission capacitor electronically coupled between the signal output device and the conductive via hole, and configured to facilitate transmitting signals from the signal output device to the signal input device.

6. A multi-layer printed circuit board comprising:
a first layer having a signal output device mounted thereon;
a second layer having a signal input device mounted thereon;
at least one third layer between the first and second layers;
a conductive via hole defined through the first, second and third layers, and electronically coupled to the signal output device and the signal input device; and
a filtering capacitor configured to electronically couple between ground and a node between the conductive via hole and the signal output device.

7. The multi-layer printed circuit board of claim 6, wherein the conductive via hole has a characteristic parasitic inductance, the filtering capacitor and the parasitic inductance of the conductive via hole cooperatively form a low-pass filter that is configured to filter noise signal induced by the conductive via hole due to the parasitic inductance.

8. The multi-layer printed circuit board of claim 6, further comprising a first transmission line and a second transmission line, wherein the signal output device is electronically coupled to an end of the conductive via hole through the first transmission line, the signal input device is electronically coupled to another end of the conductive via hole through the second transmission line.

9. The multi-layer printed circuit board of claim 8, wherein a characteristic impedance of the first transmission line is 50 ohms; a characteristic impedance of the second transmission line is 50 ohms

10. The multi-layer printed circuit board of claim 6, further comprising a transmission capacitor electronically coupled between the signal output device and the conductive via hole, and configured to facilitate transmitting signals from the signal output device to the signal input device.
